(19) United States
(12) Patent Application Publication
(10) Pub. No.: US 2019/0306972 A1
(43) Pub. Date: Oct. 3, 2019

(54) ELECTRIC ELEMENT AND ELECTRONIC DEVICE

(71) Applicant: FUJITSU LIMITED, Kawasaki-shi (JP)

(72) Inventor: Shunji Baba, Yokohama (JP)

(73) Assignee: FUJITSU LIMITED, Kawasaki-shi (JP)

(21) Appl. No.: 16/280,097

(22) Filed: Feb. 20, 2019

(30) Foreign Application Priority Data
Mar. 29, 2018 (JP) 2018-064985

(51) Int. Cl. H05K 1/02; H05K 1/14; H05K 1/16; G01B 7/16

(52) U.S. Cl. CPC H05K 1/0283; H05K 1/144; H05K 1/162; H05K 2201/058; G01B 7/18; H05K 2201/10151; H05K 2201/041; G01B 7/22

(57) ABSTRACT

An electric element includes a first substrate made of an insulator having bendability, a second substrate provided over a first surface of the first substrate and having bendability-and-elasticity, a first conductive-film formed over the second substrate, a third substrate having bendability-and-elasticity and provided over a position at which the third substrate overlaps the second substrate over a second surface of the first substrate, a second conductive-film formed at a position at which the second conductive-film overlaps the first conductive-film over the third substrate, a first lead-wire to include a first thread-like-member having conductivity and sewn into the first substrate in an elasticity state, the first thread-like-member being extended from the first conductive-film to the first substrate, and a second lead-wire to include a second thread-like-member having conductivity and sewn into the first substrate in an elasticity state, the second thread-like-member being extended from the second conductive-film to the first substrate.

### CROSS-REFERENCE TO RELATED APPLICATION

This application is based upon and claims the benefit of priority of the prior Japanese Patent Application No. 2018-064985, filed on Mar. 29, 2018, the entire contents of which are incorporated herein by reference.

### FIELD

The embodiments discussed herein are related to an electric element and an electronic device.

### BACKGROUND

The following technologies have been known as technologies for detecting a bended state of a base material such as cloth having bendability (flexibility) or a state of pressing force applied to the base material.

For example, a technology has been known which configures a capacitance type sensor by disposing electrodes on both front and rear surfaces of a dielectric layer made of an elastomer.

Also, a sensor sheet has been known which includes an insulating base material in the form of a sheet which is foldable and variable in thickness in response to pressing, a plurality of first electrodes which are arranged to be formed on the insulating base material, and a plurality of second electrodes which are arranged so as not to overlap the first electrodes.

Additionally, a stretchable conductive circuit has been known and used as a wire for a bending sensor to be mounted on a finger, an elbow joint, or a knee joint.

Related techniques are disclosed in, for example, Japanese Laid-open Patent Publication Nos. 2011-171100 and 2017-068780, and International Publication Pamphlet No. WO 2015/174505.

### SUMMARY

According to an aspect of the embodiments, an electric element includes a first substrate made of an insulator having bendability, a second substrate provided over a first surface of the first substrate and having bendability and elasticity, a first conductive film formed over the second substrate, a third substrate having bendability and elasticity and provided over a position at which the third substrate overlaps the second substrate over a second surface of the first substrate opposite to the first surface, a second conductive film formed at a position at which the second conductive film overlaps the first conductive film over the third substrate, a first lead wire configured to include a first thread-like member having conductivity and sewn into the first substrate in a state having elasticity, the first thread-like member being extended from the first conductive film to the first substrate, and a second lead wire configured to include a second thread-like member having conductivity and sewn into the first substrate in a state having elasticity, the second thread-like member being extended from the second conductive film to the first substrate.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is an exploded perspective view illustrating constituent elements of an electric element according to an embodiment of the disclosed technology;

FIG. 2 is a top plan view illustrating an example of a configuration of the electric element according to the embodiment of the disclosed technology;

FIG. 3A is a cross-sectional view taken along line 3A-3A in FIG. 2;

FIG. 3B is a cross-sectional view taken along line 3B-3B in FIG. 2;

FIG. 4A is a view illustrating examples of constituent materials of a first conductive film and a second conductive film according to the embodiment of the disclosed technology;

FIG. 4B is a view illustrating a state where the first conductive film and the second conductive film according to the embodiment of the disclosed technology are stretched;

FIG. 5A is a cross-sectional view illustrating an example of a method of elastically sewing a conductive thread-like member according to the embodiment of the disclosed technology on a base substrate;

FIG. 5B is a view illustrating a state in which the base substrate according to the embodiment of the disclosed technology is stretched in an X direction;

FIG. 6 is a perspective view illustrating another example of the method of elastically sewing the conductive thread-like member on the base substrate according to the embodiment of the disclosed technology;

FIG. 7 is an equivalent circuit diagram of the electric element according to the embodiment of the disclosed technology;

FIG. 8A is a cross-sectional view illustrating a state where the base substrate according to the embodiment of the disclosed technology is bent;

FIG. 8B is a cross-sectional view illustrating a state where the base substrate according to the embodiment of the disclosed technology is bent;

FIG. 9A is a cross-sectional view illustrating a state where the base substrate according to the embodiment of the disclosed technology is stretched;

FIG. 9B is a cross-sectional view illustrating a state where the base substrate according to the embodiment of the disclosed technology is compressed;

FIG. 10 is a cross-sectional view illustrating a state where pressing force is applied to the electric element according to the embodiment of the disclosed technology;

FIG. 11 is a top plan view illustrating an example of a configuration of an electronic device according to the embodiment of the disclosed technology;

FIG. 12 is a view illustrating an example of an electrical configuration of the electronic device according to the embodiment of the disclosed technology;

FIG. 13 is a flowchart illustrating an example of a flow of a process of detecting a bent state, a stretched state, and a contracted state of the base substrate by a measurement unit according to the embodiment of the disclosed technology; and

FIG. 14 is a flowchart illustrating an example of a flow of a process of detecting a state of pressing force applied to the electric element by the measurement unit according to the embodiment of the disclosed technology.

### DESCRIPTION OF EMBODIMENTS

For example, a configuration in which an electric element having a sensor function is disposed on a film-shaped plastic substrate mounted on a base material is considered as a configuration for detecting a bent state of the base material such as cloth having bendability (flexibility) or a state of pressing force applied to the base material. However, according to the configuration, the plastic substrate has no elasticity, and thus the plastic substrate cannot be deformed in accordance with the bending, the stretch, and the contraction of the base material, and as a result, there is concern that the plastic substrate will be separated from the base material.

Hereinafter, with reference to the drawings, the description will be made to an example of an embodiment of a technology capable of improving adaptability of the electric element, which detects deformation of the base material having bendability (flexibility), in respect to the deformation of the base material. Further, in the respective drawings, identical or equivalent constituent elements and parts are denoted by the same reference numerals, and repeated descriptions thereof will be appropriately omitted.

### First Embodiment

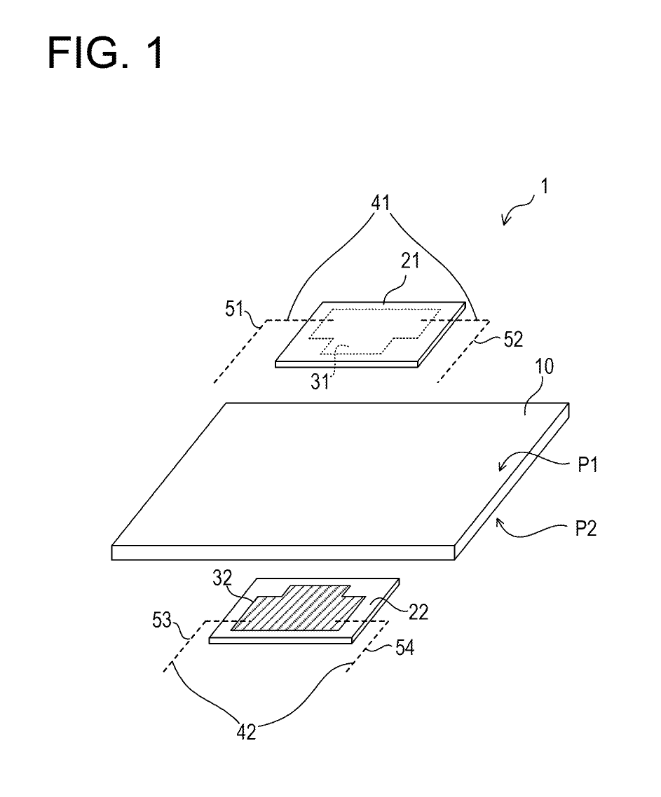

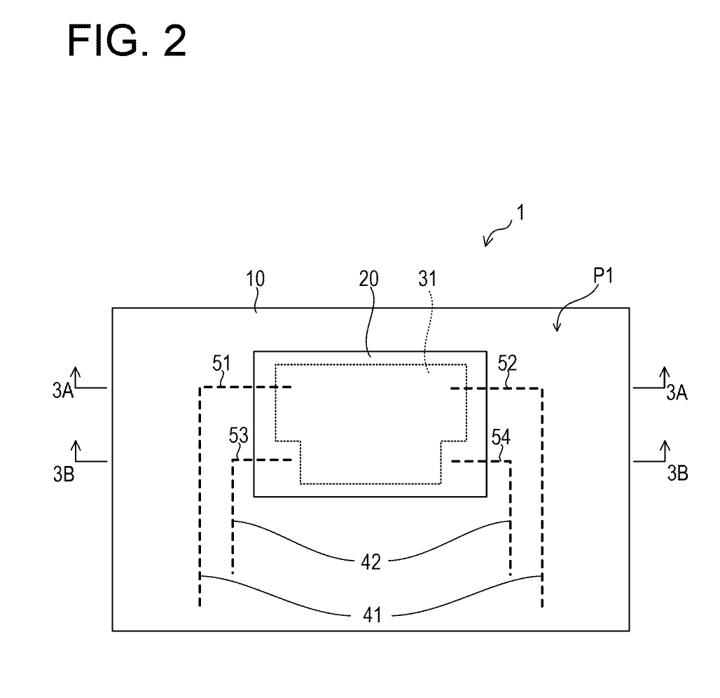

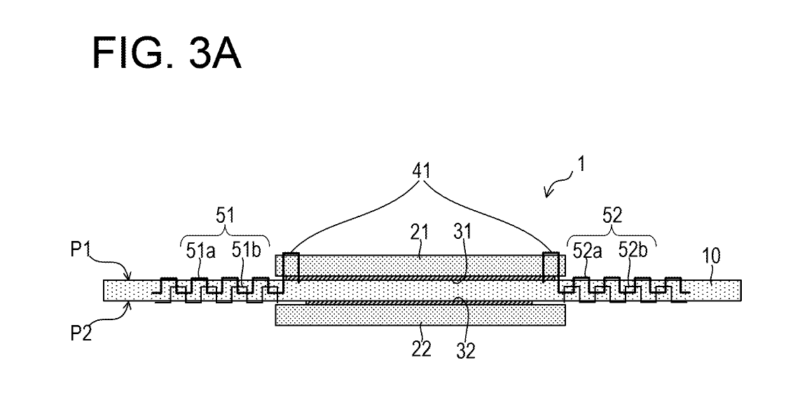

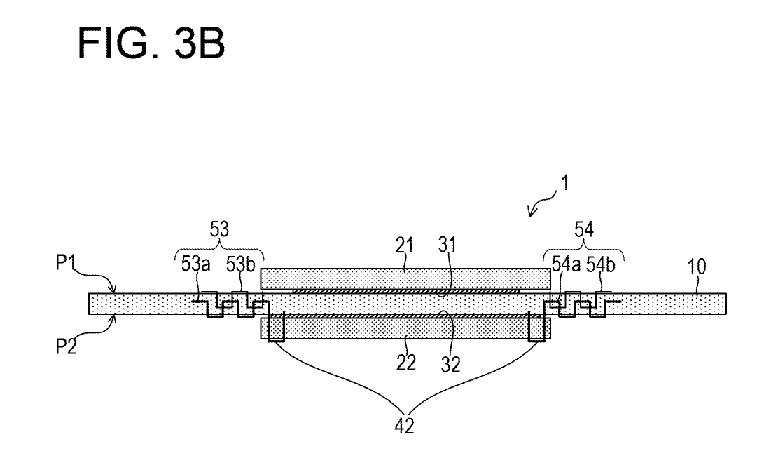

FIG. 1 is an exploded perspective view illustrating constituent elements of an electric element 1 according to a first embodiment of the disclosed technology. FIG. 2 is a top plan view illustrating an example of a configuration of the electric element 1. FIG. 3A is a cross-sectional view taken along line 3A-3A in FIG. 2. FIG. 3B is a cross-sectional view taken along line 3B-3B in FIG. 2.

The electric element 1 has a base substrate 10 made of an insulator having bendability (flexibility). The base substrate 10 may have elasticity in addition to bendability (flexibility). A material of the base substrate 10 may be, for example, cloth. In addition, rubber may be used as the material of the base substrate 10. Further, in the present specification, the description “a member has elasticity” means that the member is deformed to be stretched when tensile force is applied to the member and the member returns back to an original shape when external force is eliminated.

The electric element 1 has a first electrode substrate 21 which is provided on a first surface P1 of the base substrate 10 and has bendability (flexibility) and elasticity, and a second electrode substrate 22 which is provided on a second surface P2 opposite to the first surface P1 of the base substrate 10 and has bendability and elasticity. The second electrode substrate 22 is provided at a position on the second surface P2 of the base substrate 10 where the second electrode substrate 22 overlaps the first electrode substrate 21. That is, a part of the base substrate 10 is interposed between the first electrode substrate 21 and the second electrode substrate 22. Each of the first electrode substrate 21 and the second electrode substrate 22 may be a rubber substrate including rubber.

A first conductive film 31 is provided on a contact surface of the first electrode substrate 21 which is in contact with the base substrate 10. Similarly, a second conductive film 32 is provided on a contact surface of the second electrode substrate 22 which is in contact with the base substrate 10. The second conductive film 32 is provided at a position on the second electrode substrate 22 where the second conductive film 32 overlaps the first conductive film 31. That is, a part of the base substrate 10 is interposed between the first conductive film 31 and the second conductive film 32.

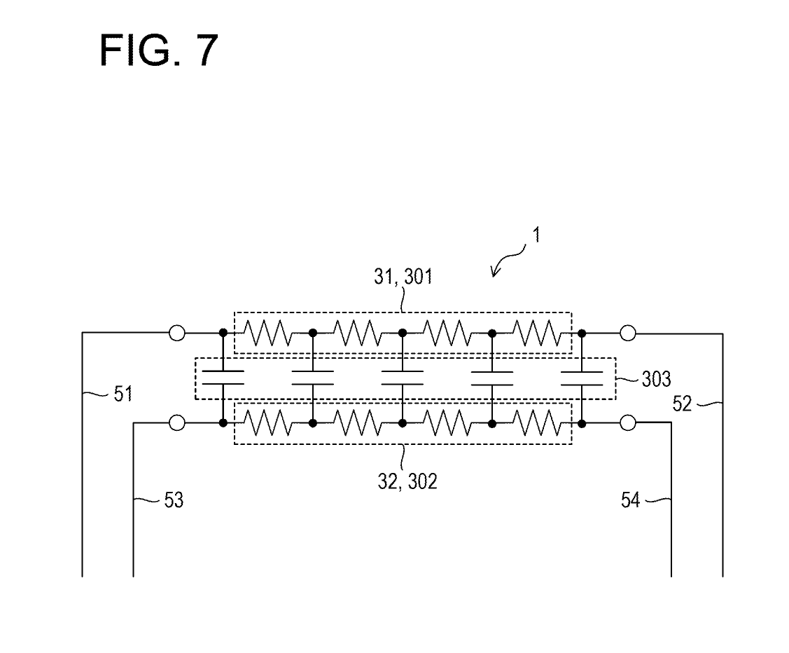

The base substrate 10, which is an insulator, is interposed between the first conductive film 31 and the second conductive film 32, so that a capacitor 303 (see FIG. 7) is configured. Each of the first conductive film 31 and the second conductive film 32 functions as an electrode of the capacitor 303, and the base substrate 10 functions as a dielectric of the capacitor 303. Further, the first conductive film 31 may be provided on a surface opposite to the contact surface of the first electrode substrate 21 which is in contact with the base substrate 10. Similarly, the second conductive film 32 may be provided on a surface opposite to the contact surface of the second electrode substrate which is in contact with the base substrate 10.

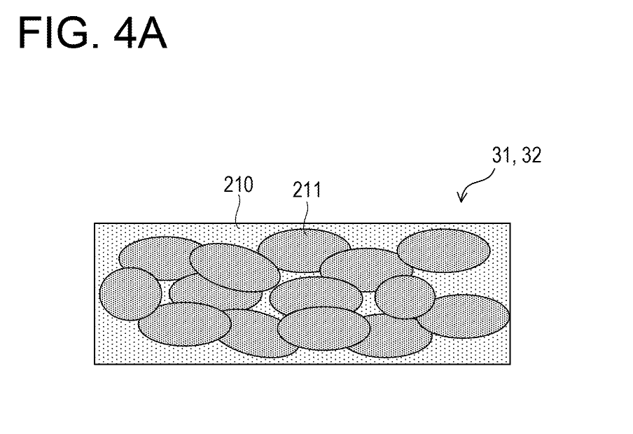

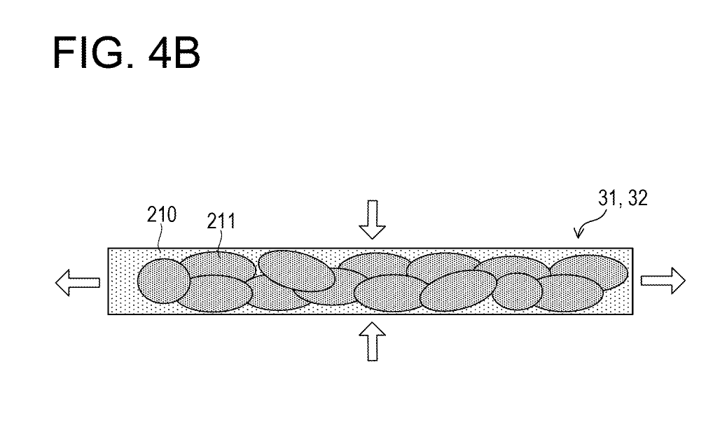

As illustrated in FIG. 4A, each of the first conductive film 31 and the second conductive film 32 may be made of conductive rubber made by dispersing conductive particles 211 into a binder 210 made of a rubber-based material having elasticity. Since the binder 210 is made of a rubber-based material, the first conductive film 31 and the second conductive film 32 may be stretched and contracted in accordance with the stretch and the contraction of the first electrode substrate 21 and the second electrode substrate 22, respectively. FIG. 4B is a view illustrating a state where the first conductive film 31 and the second conductive film 32 are stretched in a lateral direction based on the drawing. As the binder 210 made of a rubber-based material is stretched in the lateral direction based on the drawing, compressive force is applied in a longitudinal direction based on the drawing, so that the contact between the conductive particles 211 is maintained. Therefore, the conductivity of the first conductive film 31 and the second conductive film 32 is maintained even in the case where the first conductive film 31 and the second conductive films 32 are stretched and contracted in accordance with the stretch and the contraction of the first electrode substrate 21 and the second electrode substrate 22, respectively.

The electric element 1 has first lead wires 41 extended from the first conductive film 31 to the base substrate 10. In addition, the electric element 1 has second lead wires 42 extended from the second conductive film 32 to the base substrate 10.

The first lead wires 41 include a first wire 51 which is extended from one end of the first conductive film 31 to the base substrate 10 and includes conductive thread-like members 51a and 51b (see FIG. 3A) elastically sewn into the base substrate 10. In addition, the first lead wires 41 include a second wire 52 which is extended from the other end of the first conductive film 31 to the base substrate 10 and includes conductive thread-like members 52a and 52b (see FIG. 3A) elastically sewn into the base substrate 10. Each of the first wire 51 and the second wire 52 is electrically connected to the first conductive film 31.

The second lead wires 42 include a third wire 53 which is extended from one end of the second conductive film 32 to the base substrate 10 and includes conductive thread-like members 53a and 53b (see FIG. 3B) elastically sewn into the base substrate 10. In addition, the second lead wires 42 include a fourth wire 54 which is extended from the other end of the second conductive film 32 to the base substrate 10 and includes conductive thread-like members 54a and 54b (see FIG. 3B) elastically sewn into the base substrate 10. The third wire 53 and the fourth wire 54 are electrically connected to the second conductive film 32.

As the conductive thread-like members 51a to 54a and 51b to 54b, for example, a substance made by uniformly dispersing metal or graphite having conductivity into a synthetic fiber may be used, or a metallic fiber made of metal by fiberizing may be used. In addition, examples of the conductive thread-like members 51a to 54a and 51b to 54b include a substance made by coating a surface of an organic fiber with metal, or a substance made by coating a surface of an organic fiber with resin including a conductive material.

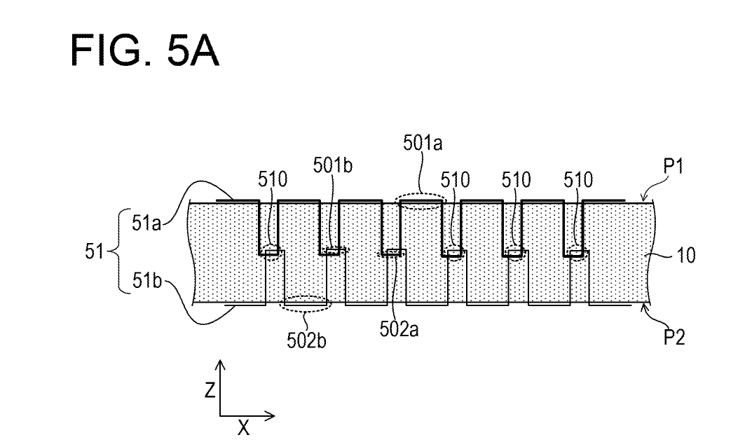

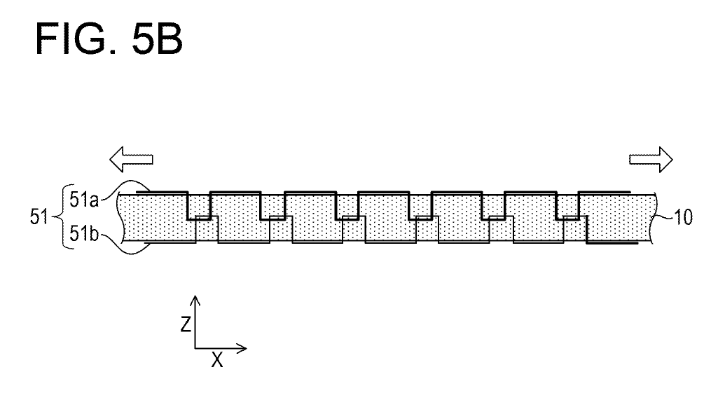

FIG. 5A is a cross-sectional view illustrating an example of a method of elastically sewing, on the base substrate 10, the conductive thread-like members 51a and 51b that constitute the first wire 51. Further, the same sewing method may also be applied to the conductive thread-like members 52a to 54a and 52b to 54b that constitute the second wire 52, the third wire 53, and the fourth wire 54.

Here, an extension direction of the first wire 51 is defined as an X direction, and a direction which is a thickness direction of the base substrate 10 and is orthogonal to the X direction is defined as a Z direction. The conductive thread-like member 51a meanders in a plane (X-Z plane) that intersects with the first surface P1, which is a principal surface of the base substrate 10, and the second surface P2 opposite to the first surface P1 so as to form a plurality of folded portions 501a and 502a. Similarly, the conductive thread-like member 51b meanders in the plane (X-Z plane) that intersects with the first surface P1 and the second surface P2 of the base substrate 10 so as to form a plurality of folded portions 501b and 502b. The folded portions 501b of the conductive thread-like member 51b are interlaced with the folded portions 502a at one side of the conductive thread-like member 51a, respectively. That is, interlaced portions 510 are formed as the folded portions 502a and 501b of the conductive thread-like members 51a and 51b are interlaced with one another. In the present embodiment, surfaces of the conductive thread-like members 51a and 51b at least have conductivity and the conductive thread-like members 51a and 51b are electrically connected to each other through the interlaced portions 510. That is, the single first wire 51 is formed by the two conductive thread-like members 51a and 51b.

FIG. 58 is a view illustrating a state where the base substrate 10 is stretched in the X direction. As the base substrate 10 is stretched in the X direction and thus the base substrate 10 is deformed, the conductive thread-like members 51a and 51b are deformed in accordance with the deformation of the base substrate 10. Even in a case where the conductive thread-like members 51a and 51b have no elasticity, the first wire 51 may be stretched and contracted in accordance with the bending (flexion), the stretch, and the contraction of the base substrate 10 because the conductive thread-like members 51a and 51b are sewn into the base substrate 10 such that the conductive thread-like members 51a and 51b meander. In addition, electric conduction may be maintained in the first wire 51 even in a case where any one of the two conductive thread-like members 51a and 51b is disconnected.

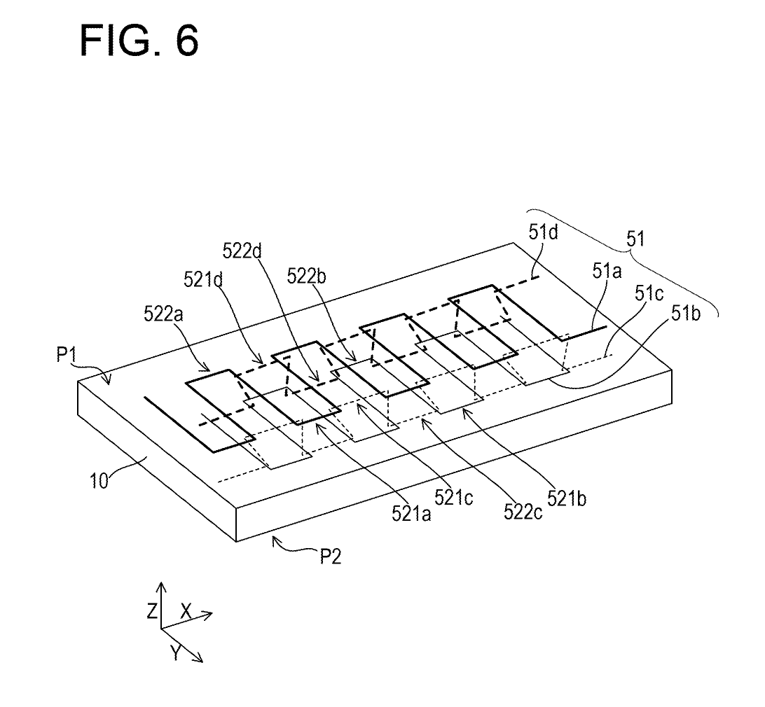

FIG. 6 is a perspective view illustrating another example of the method of elastically sewing, on the base substrate 10, the conductive thread-like members that constitute the first wire 51. Further, the same sewing method may also be applied to the conductive thread-like members that constitute the second wire 52, the third wire 53, and the fourth wire 54.

In the example illustrated in FIG. 6, the first wire 51 includes four conductive thread-like members 51a, 51b, 51c, and 51d. Further, in FIG. 6, in a point of view of discrimination of the plurality of conductive thread-like members, the conductive thread-like members 51c and 51d are indicated by broken lines. In addition, the extension direction of the first wire 51 is defined as the X direction, the direction, which is the thickness direction of the base substrate 10 and is orthogonal to the X direction, is defined as the Z direction, and a direction, which is orthogonal to both of the X direction and the Z direction, is defined as a Y direction.

The conductive thread-like member 51a is provided at the side of the first surface P1 of the base substrate 10, and the conductive thread-like member 51a meanders in a plane parallel to the first surface P1 of the base substrate 10 so as to form a plurality of folded portions 521a and 522a.

The conductive thread-like member 51b is provided at the side of the second surface P2 of the base substrate 10, and the conductive thread-like member 51b meanders in a plane parallel to the second surface P2 of the base substrate 10 so as to form a plurality of folded portions 521b and 522b.

The conductive thread-like member 51c meanders in the plane (X-Z plane) that intersects with the first surface P1 and the second surface P2 of the base substrate 10 so as to form a plurality of folded portions 521c and 522c. The folded portions 521c of the conductive thread-like member 51c are interlaced with the folded portions 521a of the conductive thread-like member 51a, respectively, and the folded portions 522c of the conductive thread-like member 51c are interlaced with the folded portions 521b of the conductive thread-like member 51b, respectively.

The conductive thread-like member 51d meanders in the plane (X-Z plane) that intersects with the first surface P1 and the second surface P2 of the base substrate 10 so as to form a plurality of folded portions 521d and 522d. The folded portions 521d of the conductive thread-like member 51d are interlaced with the folded portions 522a of the conductive thread-like member 51a, respectively, and the folded portions 522d of the conductive thread-like member 51d are interlaced with the folded portions 522b of the conductive thread-like member 51b, respectively.

Since the four conductive thread-like members 51a, 51b, 51c, and 51d are sewn into the base substrate 10 as described above, the first wire 51 may have high elasticity not only in the X direction but also in the Y direction.

It is possible to further reduce a resistance value of the first wire 51 by increasing the number of conductive thread-like members that constitute the first wire 51. Moreover, it is possible to improve reliability by improving redundancy of the first wire 51.

FIG. 7 is an equivalent circuit diagram of the electric element 1. The first conductive film 31 may be regarded as a resistance element 301. A resistance value R1 of the resistance element 301 (i.e., a resistance value between one end and the other end of the first conductive film 31) may be measured through the first wire 51 and the second wire 52. Similarly, the second conductive film 32 may be regarded as a resistance element 302. A resistance value R2 of the resistance element 302 (i.e., a resistance value between one end and the other end of the second conductive film 32) may be measured through the second wire 52 and the third wire 53.

A laminated body of the first conductive film 31, the base substrate 10, and the second conductive film 32 may be regarded as the capacitor 303. A capacitance value C of the capacitor 303 may be measured through one of the first wire 51 and the second wire 52 and one of the third wire 53 and the fourth wire 54.

According to the electric element 1 according to the embodiment of the disclosed technology, the first electrode substrate 21 and the second electrode substrate 22 have bendability and elasticity, and as a result, the first electrode substrate 21 and the second electrode substrate 22 may be bent, stretched, and contracted in accordance with the bending, the stretch, and the contraction of the base substrate 10. Therefore, it is possible to inhibit a risk that the first electrode substrate 21 and the second electrode substrate 22 are separated from the base substrate 10 when the base substrate 10 is bent, stretched, or contracted.

According to the electric element 1, based on electrical properties of the electric element 1, it is possible to detect a bent state (presence or absence of a bent portion and a degree of bending) of the base substrate 10 at a position where the electric element 1 is mounted.

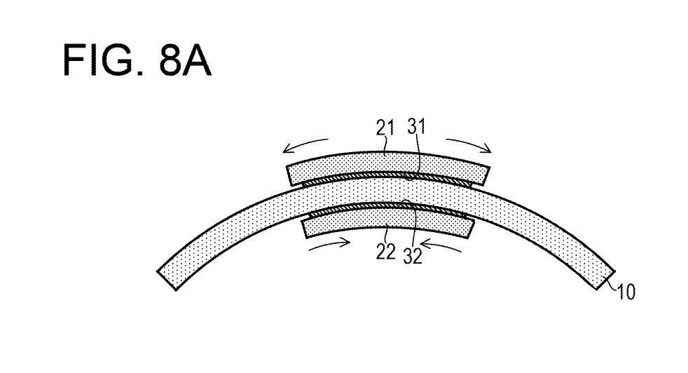

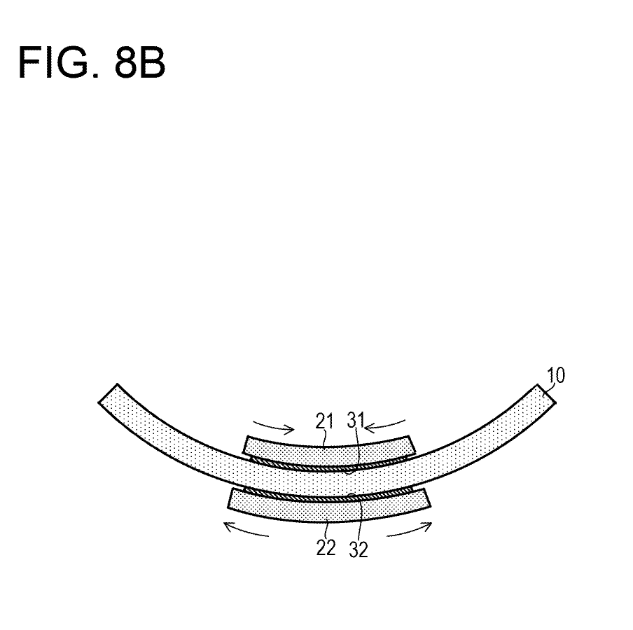

For example, as illustrated in FIG. 8A, in a case where the base substrate 10 is bent such that the first conductive film 31 is positioned outside a bent portion and the second conductive film 32 is positioned inside the bent portion, the first conductive film 31 is stretched together with the first electrode substrate 21 and the second conductive film 32 is contracted together with the second electrode substrate 22. Therefore, in this case, the resistance value R1 of the first conductive film 31 is increased from an initial state, and the resistance value R2 of the second conductive film 32 is decreased from the initial state. Therefore, assuming that the amount of change in resistance value R1 from the initial state is ΔR1 and the amount of change in resistance value R2 from the initial state is ΔR2, it may be determined that the base substrate 10 is bent in a mode illustrated in FIG. 8A in the case of ΔR2<0<ΔR1. Further, the initial state is a state where the base substrate 10 does not experience the deformation such as bending and stretch. In addition, a degree of bending (bending amount) may be derived from magnitudes of ΔR1 and ΔR2 or magnitudes of the resistance values R1 and R2. Further, in the case of ΔR2<ΔR1, it may be determined that the base substrate 10 is bent in the mode illustrated in FIG. 8A.

Meanwhile, as illustrated in FIG. 8B, in a case where the base substrate 10 is bent such that the second conductive film 32 is positioned outside a bent portion and the first conductive film 31 is positioned inside the bent portion, the second conductive film 32 is stretched together with the second electrode substrate 22 and the first conductive film 31 is contracted together with the first electrode substrate 21. Therefore, in this case, the resistance value R2 of the second conductive film 32 is increased from the initial state, and the resistance value R1 of the first conductive film 31 is decreased from the initial state. Therefore, in the case of ΔR1<0<ΔR2, it may be determined that the base substrate 10 is bent in a mode illustrated in FIG. 8B. In addition, a degree of bending (bending amount) may be derived from the magnitudes of ΔR1 and ΔR2 or the magnitudes of the resistance values R1 and R2. Further, in the case of ΔR1<ΔR2, it may be determined that the base substrate 10 is bent in the mode illustrated in FIG. 8B.

According to the electric element 1, based on the electrical properties of the electric element 1, it is possible to detect a stretched or contracted state (presence or absence of stretch or contraction and a degree of stretch or contraction) of the base substrate 10 at a position where the electric element 1 is mounted.

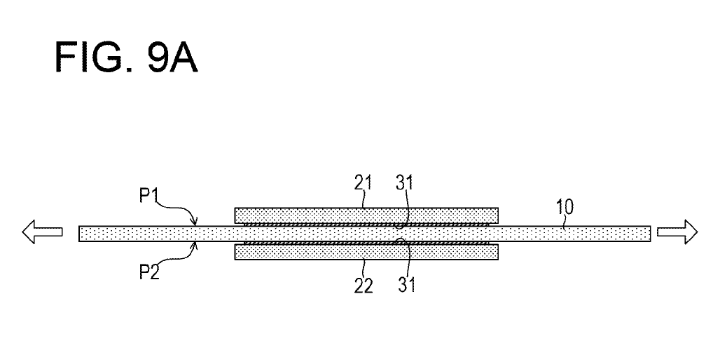

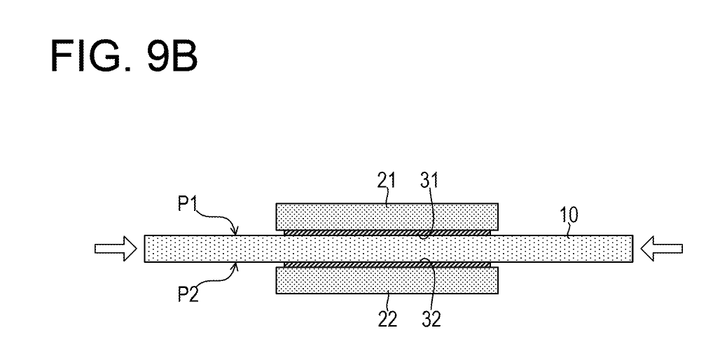

For example, as illustrated in FIG. 9A, in a case where the base substrate 10 is stretched in a direction parallel to the first surface P1 and the second surface P2, the first conductive film 31 is stretched together with the first electrode substrate 21 and the second conductive film 32 is stretched together with the second electrode substrate 22. Therefore, in this case, the resistance value R1 of the first conductive film 31 and the resistance value R2 of the second conductive film 32 are increased from the initial state where the base substrate 10 is not deformed. Therefore, in the case of 0<ΔR1 and 0<ΔR2, it may be determined that the base substrate 10 is stretched in a mode illustrated in FIG. 9A. In addition, a degree of stretch (stretch amount) may be derived from the magnitudes of ΔR1 and ΔR2 or the magnitudes of the resistance values R1 and R2.

As illustrated in FIG. 9B, in a case where the base substrate 10 is compressed in a direction parallel to the first surface P1 and the second surface P2, the first conductive film 31 is contracted together with the first electrode substrate 21 and the second conductive film 32 is contracted together with the second electrode substrate 22. Therefore, in this case, the resistance value R1 of the first conductive film 31 and the resistance value R2 of the second conductive film 32 are decreased from the initial state where the base substrate 10 is not deformed. Therefore, in the case of 0>ΔR1 and 0>ΔR2, it may be determined that the base substrate 10 is compressed in a mode illustrated in FIG. 9B. In addition, a degree of compression (compression amount) may be determined from the magnitudes of ΔR1 and ΔR2 or the magnitudes of the resistance values R1 and R2.

According to the electric element 1, based on the electrical properties of the electric element 1, it is possible to detect a state of the pressing force (presence or absence of pressing force and a magnitude of pressing force) applied to the electric element 1.

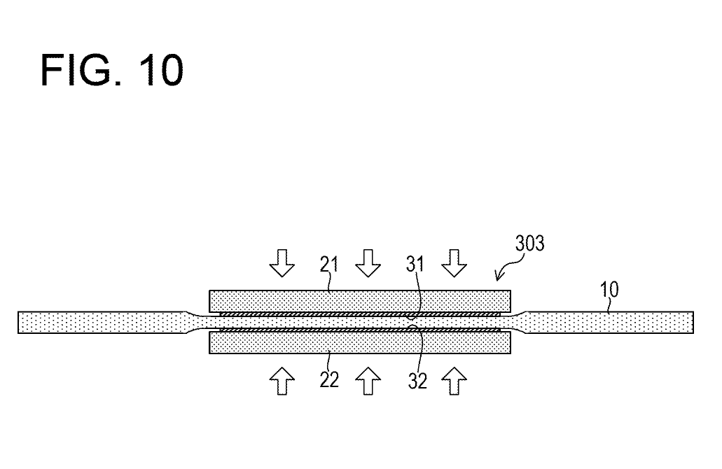

For example, as illustrated in FIG. 10, in a case where pressing force is applied to the electric element 1, the base substrate 10 interposed between the first conductive film 31 and the second conductive film 32 is compressed, so that a distance between the first conductive film 31 and the second conductive film 32 is changed. Therefore, the capacitance value C of the capacitor 303, which is configured by the laminated body of the first conductive film 31, the base substrate 10, and the second conductive film 32, is changed. Therefore, based on the capacitance value C of the capacitor 303 measured through one of the first wire 51 and the second wire 52 and one of the third wire 53 and the fourth wire 54, it is possible to detect a state of the pressing force applied at a position on the base substrate 10 at which the electric element 1 is mounted. For example, in a case where the amount ΔC of change in capacitance value C from the initial state where no pressing force is applied is larger than a threshold value C1, it may be determined that the pressing force is applied to the electric element 1. In addition, a degree of pressing (a magnitude of pressing force) applied to the electric element 1 may be derived from a magnitude of ΔC or the capacitance value C.

According to the electric element 1, the first to fourth wires 51 to 54 are configured by the conductive thread-like members elastically sewn into the base substrate 10, and as a result, the first to fourth wires 51 to 54 may be bent, stretched and contracted in accordance with the bending, the stretch, and the contraction of the base substrate 10. Here, a case where each of the first to fourth wires 51 to 54 is configured by conductive rubber provided on the first electrode substrate 21 or the second electrode substrate 22 is considered. In this case, the first to fourth wires 51 to 54 may be bent, stretched, and contracted in accordance with the bending, the stretch, and the contraction of the base substrate 10, but the resistance values of the wires are changed when the first to fourth wires 51 to 54 are stretched and contracted. Therefore, it is difficult to detect a bent state, a stretched state, and a contracted state of the base substrate 10 based on the resistance value R1 of the first conductive film 31 and the resistance value R2 of the second conductive film 32. Meanwhile, according to the electric element 1 according to the embodiment of the disclosed technology, the resistance values of the wires are not changed even in the case where the first to fourth wires 51 to 54 are bent, stretched, and contracted in accordance with the bending, the stretch, and the contraction of the base substrate 10. Therefore, it is possible to detect a bent state, a stretched state, and a contracted state of the base substrate 10 based on the resistance value R1 of the first conductive film 31 and the resistance value R2 of the second conductive film 32.

In the present embodiment, the configuration in which the two wires are extended from the first conductive film 31 and the two wires are extended from the second conductive film 32 has been described as an example, but the present embodiment is not limited to this mode. The first lead wire 41 may be configured by a single wire connected to the first conductive film 31, and the second lead wire 42 may be configured by a single wire connected to the second conductive film 32. In this case, the capacitance value of the capacitor 303 may be measured.

The first lead wires 41 may be configured by two wires connected to one end and the other end of the first conductive film 31, and the second lead wire 42 may be configured by a single wire connected to the second conductive film 32. In this case, the resistance value R1 of the first conductive film 31 and the capacitance value C of the capacitor 303 may be measured.

The first lead wire 41 may be configured by a single wire connected to the first conductive film 31, and the second lead wires 42 may be configured by two wires connected to one end and the other end of the second conductive film 32. In this case, the resistance value R2 of the second conductive film 32 and the capacitance value C of the capacitor 303 may be measured.

As described above, according to the electric element 1 according to the embodiment of the disclosed technology, it is possible to detect a bent state, a stretched state, and a contracted state of the base substrate 10 having bendability (flexibility), and thus it is possible to improve adaptability to the deformation of the base substrate 10. For example, the electric element 1 may be mounted on a joint portion in a clothed state, and the electric element 1 may be used to detect the motion of the joint.

### Second Embodiment

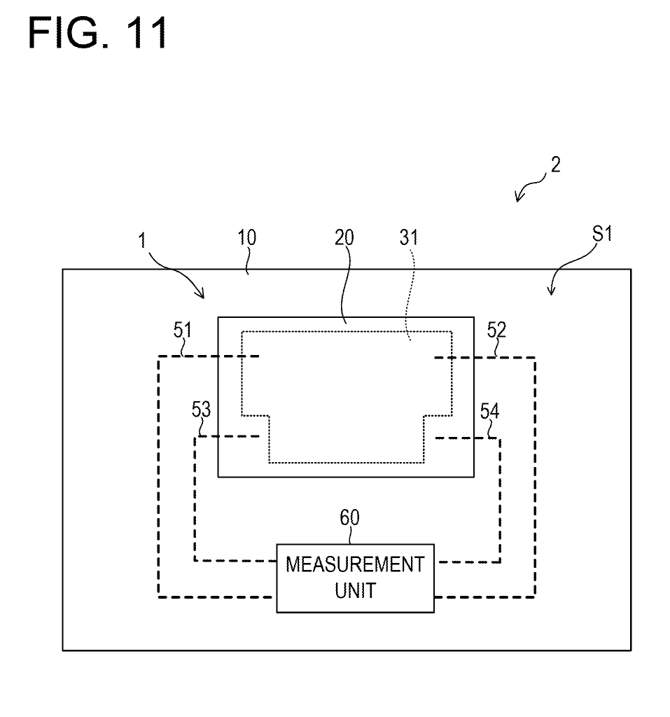

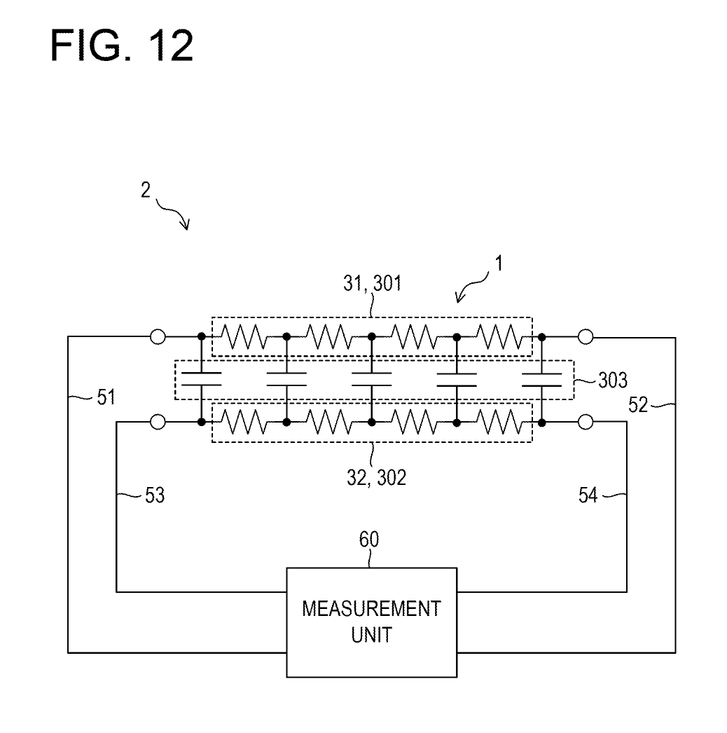

FIG. 11 is a top plan view illustrating an example of a configuration of an electronic device 2 according to a second embodiment of the disclosed technology. FIG. 12 is a view illustrating an example of an electrical configuration of the electronic device 2.

The electronic device 2 has the electric element 1, and a measurement unit 60 that measures electrical properties of the electric element 1. The measurement unit 60 is mounted on the base substrate 10. The measurement unit 60 is connected to the first wire 51 and the second wire 52 connected to the first conductive film 31 of the electric element 1, and the measurement unit 60 is connected to the third wire 53 and the fourth wire 54 connected to the second conductive film 32 of the electric element 1.

The measurement unit 60 measures the resistance value R1 of the first conductive film 31 through the first wire 51 and the second wire 52. In addition, the measurement unit 60 measures the resistance value R2 of the second conductive film 32 through the third wire 53 and the fourth wire 54. In addition, through one of the first wire 51 and the second wire 52 and one of the third wire 53 and the fourth wire 54, the measurement unit 60 measures the capacitance value C of the capacitor 303 which is configured by the laminated body of the first conductive film 31, the base substrate 10, and the second conductive film 32.

Based on the measured resistance value R1 of the first conductive film 31 and the measured resistance value R2 of the second conductive film 32, the measurement unit 60 detects the bent state, the stretched state, and the contracted state of the base substrate 10 at a position where the electric element 1 is mounted.

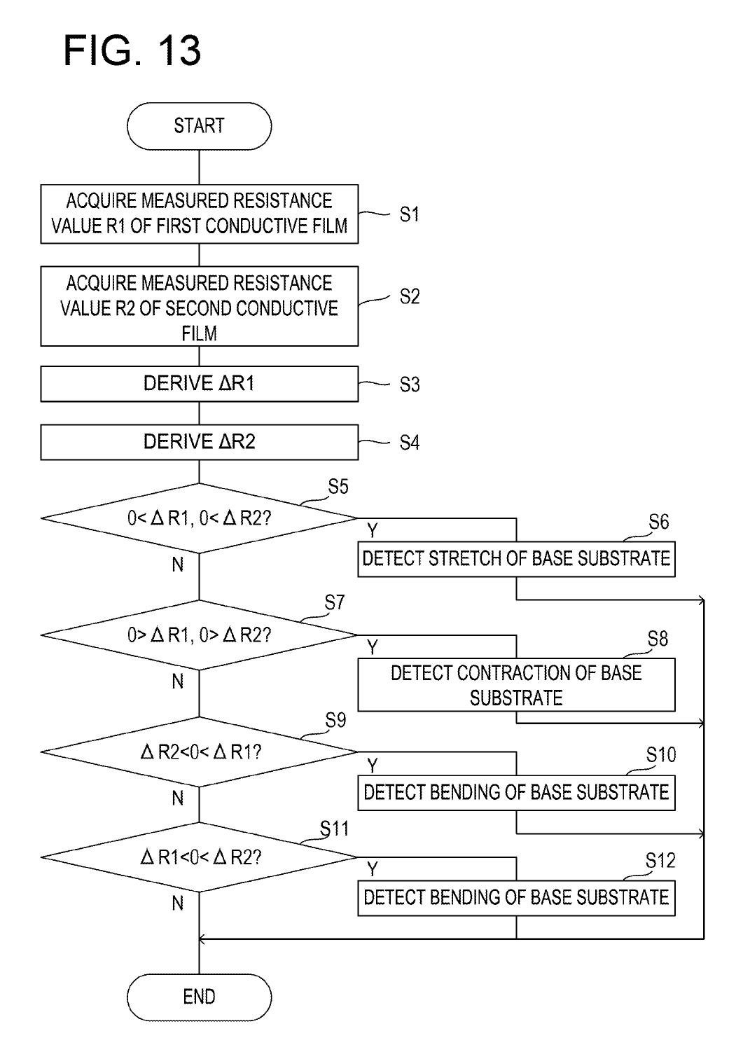

FIG. 13 is a flowchart illustrating an example of a flow of a process of detecting, by the measurement unit 60, the bent state, the stretched state, and the contracted state of the base substrate 10 at the position where the electric element 1 is mounted, based on the measured resistance value R1 of the first conductive film 31 and the measured resistance value R2 of the second conductive film 32.

In operation S1, the measurement unit 60 measures the resistance value R1 of the first conductive film 31 and acquires the measured resistance value R1.

In operation S2, the measurement unit 60 measures the resistance value R2 of the second conductive film 32 and acquires the measured resistance value R2.

In operation S3, the measurement unit 60 derives the amount ΔR1 of change in respect to the measured resistance value R1 from the initial state where the base substrate 10 is not deformed.

In operation S4, the measurement unit 60 derives the amount ΔR2 of change in respect to the measured resistance value R2 from the initial state where the base substrate 10 is not deformed.

In operation S5, the measurement unit 60 determines whether 0<ΔR1 and 0<ΔR2 are satisfied. That is, the measurement unit 60 determines whether the resistance value R1 of the first conductive film 31 and the resistance value R2 of the second conductive film 32 are increased from the initial state. The process proceeds to operation S6 in a case where the measurement unit 60 determines that 0<ΔR1 and 0<ΔR2 are satisfied, but the process proceeds to operation S7 in a case where the measurement unit 60 determines that 0<ΔR1 and 0<ΔR2 are not satisfied.

In operation S6, the measurement unit 60 detects that the base substrate 10 is stretched in the direction parallel to the first surface P1 and the second surface P2, as illustrated in FIG. 9A, at the position on the base substrate 10 at which the electric element 1 is mounted. The measurement unit 60 may derive a degree of stretch (stretch amount) of the base substrate 10 based on the magnitudes of ΔR1 and ΔR2 or the measured resistance value R1 and the measured resistance value R2. The measurement unit 60 outputs a detection result.

In operation S7, the measurement unit 60 determines whether 0>ΔR1 and 0>ΔR2 are satisfied. That is, the measurement unit 60 determines whether the resistance value R1 of the first conductive film 31 and the resistance value R2 of the second conductive film 32 are decreased from the initial state. The process proceeds to operation S8 in a case where the measurement unit 60 determines that 0>ΔR1 and 0>ΔR2 are satisfied, but the process proceeds to operation S9 in a case where the measurement unit 60 determines that 0>ΔR1 and 0>ΔR2 are not satisfied.

In operation S8, the measurement unit 60 detects that the base substrate 10 is compressed in the direction parallel to the first surface P1 and the second surface P2, as illustrated in FIG. 9B, at the position on the base substrate 10 at which the electric element 1 is mounted. The measurement unit 60 may derive a degree of compression (compression amount) of the base substrate 10 from the magnitudes of ΔR1 and ΔR2 or the measured resistance value R1 and the measured resistance value R2. The measurement unit 60 outputs a detection result.

In operation S9, the measurement unit 60 determines whether ΔR2<0<ΔR1 is satisfied. That is, the measurement unit 60 determines whether the resistance value R1 of the first conductive film 31 is increased from the initial state and the resistance value R2 of the second conductive film 32 is decreased from the initial state. The process proceeds to operation S10 in a case where the measurement unit 60 determines that ΔR2<0<ΔR1 is satisfied, and the process proceeds to operation S11 in a case where the measurement unit 60 determines that ΔR2<0<ΔR1 is not satisfied. Further, in operation S9, the measurement unit 60 may determine whether ΔR2<ΔR1 is satisfied.

In operation S10, the measurement unit 60 detects that the base substrate 10 is bent such that the first conductive film 31 is positioned outside the bent portion and the second conductive film 32 is positioned inside the bent portion, as illustrated in FIG. 8A. The measurement unit 60 may derive a degree of bending (bending amount) of the base substrate 10 from the magnitudes of ΔR1 and ΔR2 or the measured resistance value R1 and the measured resistance value R2. The measurement unit 60 outputs a detection result.

In operation S11, the measurement unit 60 determines whether ΔR1<0<ΔR2 is satisfied. That is, the measurement unit 60 determines whether the resistance value R1 of the first conductive film 31 is decreased from the initial state and the resistance value R2 of the second conductive film 32 is increased from the initial state. The process proceeds to operation S12 in a case where the measurement unit 60 determines that ΔR1<0<ΔR2 is satisfied, but the process is ended in a case where the measurement unit 60 determines that ΔR1<0<ΔR2 is not satisfied. Further, in operation S11, the measurement unit 60 may determine whether ΔR1<ΔR2 is satisfied.

In operation S12, the measurement unit 60 detects that the base substrate 10 is bent such that the second conductive film 32 is positioned outside the bent portion and the first conductive film 31 is positioned inside the bent portion, as illustrated in FIG. 8B. The measurement unit 60 may derive a degree of bending (bending amount) of the base substrate 10 from the magnitudes of ΔR1 and ΔR2 or the measured resistance value R1 and the measured resistance value R2. The measurement unit 60 outputs a detection result.

The measurement unit 60 detects a state of the pressing force applied to the electric element 1 based on the measured capacitance value C of the capacitor 303.

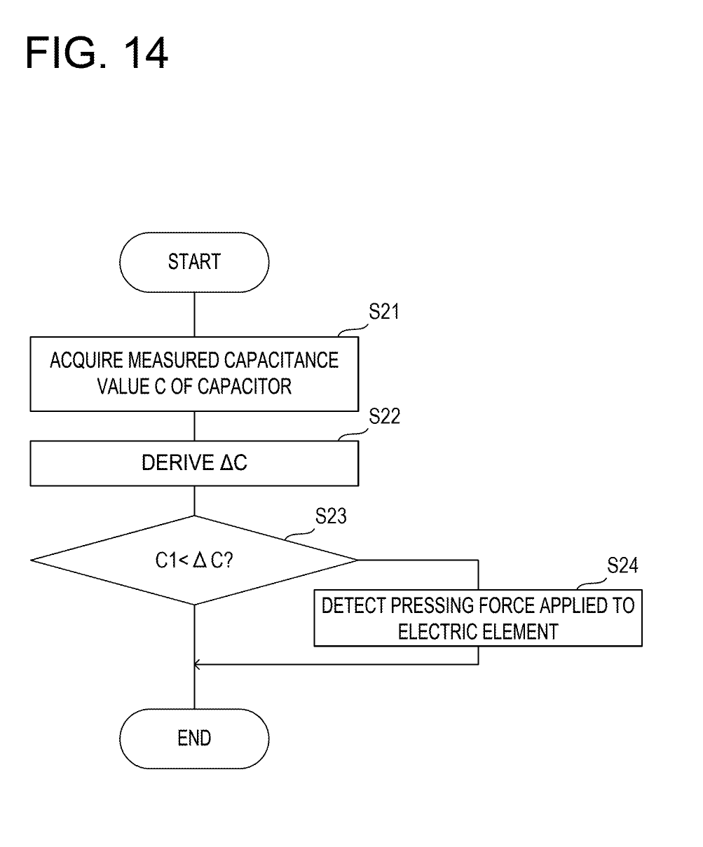

FIG. 14 is a flowchart illustrating an example of a flow of a process of detecting, by the measurement unit 60, the state of the pressing force applied to the electric element 1 based on the measured capacitance value C of the capacitor 303.

In operation S21, the measurement unit 60 measures the capacitance value C of the capacitor 303 and acquires the measured capacitance value C.

In operation S22, the measurement unit 60 derives the amount ΔC of change in respect to the measured capacitance value C from the initial state where no pressing force is applied to the electric element 1.

In operation S23, the measurement unit 60 determines whether C1<ΔC is satisfied. Further, C1 is a threshold value for detecting the pressing force. That is, the measurement unit 60 determines whether the capacitance value C of the capacitor 303 is increased from the initial state by the increase amount larger than the threshold value C1. The process proceeds to operation S24 in a case where the measurement unit 60 determines that C1<ΔC is satisfied, but the process is ended in a case where the measurement unit 60 determines that C1<ΔC is not satisfied.

In operation S24, the measurement unit 60 detects that the pressing force is applied to the electric element 1, as illustrated in FIG. 10. The measurement unit 60 may derive a degree of pressing force (a magnitude of pressing force) applied to the electric element 1 from the magnitude of ΔC or the measured capacitance value C. The measurement unit 60 outputs a detection result.

As described above, according to the electronic device 2 according to the embodiment of the disclosed technology, it is possible to detect, based on the electrical properties of the electric element 1, the bent state, the stretched state, and the contracted state of the base substrate 10 at the position where the electric element 1 is mounted, and the state of the pressing force applied to the electric element 1.

The electric element 1 is an example of an electric element according to the disclosed technology. The base substrate 10 is an example of a first substrate according to the disclosed technology. The first electrode substrate 21 is an example of a second substrate according to the disclosed technology. The second electrode substrate 22 is an example of a third substrate according to the disclosed technology. The first conductive film 31 is an example of a first conductive film according to the disclosed technology. The second conductive film 32 is an example of a second conductive film according to the disclosed technology. The first lead wire 41 is an example of a first lead wire according to the disclosed technology. The second lead wire 42 is an example of a second lead wire according to the disclosed technology. The first wire 51 is an example of a first wire according to the disclosed technology. The second wire 52 is an example of a second wire according to the disclosed technology. The third wire 53 is an example of a third wire according to the disclosed technology. The fourth wire 54 is an example of a fourth wire according to the disclosed technology. The electronic device 2 is an example of an electronic device according to the disclosed technology. The measurement unit 60 is an example of a measurement unit according to the disclosed technology.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to an illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. An electric element comprising:
a first substrate made of an insulator having bendability;
a second substrate provided over a first surface of the first substrate and having bendability and elasticity;
a first conductive film formed over the second substrate;
a third substrate having bendability and elasticity and provided over a position at which the third substrate overlaps the second substrate over a second surface of the first substrate opposite to the first surface;
a second conductive film formed at a position at which the second conductive film overlaps the first conductive film over the third substrate;
a first lead wire configured to include a first thread-like member having conductivity and sewn into the first substrate in a state having elasticity, the first thread-like member being extended from the first conductive film to the first substrate; and
a second lead wire configured to include a second thread-like member having conductivity and sewn into the first substrate in a state having elasticity, the second thread-like member being extended from the second conductive film to the first substrate.

2. The electric element according to claim 1,
wherein the first lead wire is configured to include:
a first wire configured to include a third thread-like member having conductivity and sewn into the first substrate in a state having elasticity, the third thread-like member being extended from a first end of the first conductive film to the first substrate; and
a second wire configured to include a fourth thread-like member having conductivity and sewn into the first substrate in a state having elasticity, the fourth thread-like member being extended from a second end of the first conductive film to the first substrate, and
wherein the second lead wire is configured to include:
a third wire configured to include a fifth thread-like member having conductivity and sewn into the first substrate in a state having elasticity, the fifth thread-like member being extended from a first end of the second conductive film to the first substrate; and
a fourth wire configured to include a sixth thread-like member having conductivity and sewn into the first substrate in a state having elasticity, the sixth thread-like member being extended from a second end of the second conductive film to the first substrate.

3. The electric element according to claim 1,
wherein the first substrate has elasticity.

4. The electric element according to claim 1,
wherein the first substrate is configured to include cloth.

5. The electric element according to claim 1,
wherein each of the second substrate and the third substrate is configured to include rubber.

6. The electric element according to claim 1,
wherein each of the first conductive film and the second conductive film is configured to make of conductive rubber made by dispersing conductive particles in a binder configured to include rubber.

7. The electric element according to claim 2,
wherein each of the first wire to the fourth wire is configured to include a seventh thread-like member and a eighth thread-like member each having conductivity and sewn to meander into the first substrate, the seventh thread-like member and the eighth thread-like member each being interlaced with each other to form a plurality of interlaced portions.

8. The electric element according to claim 7,
wherein the seventh thread-like member and the eighth thread-like member each having conductivity are electrically, the seventh thread-like member and the eighth thread-like member being coupled to each other through the interlaced portions.

9. The electric element according to claim 7,
wherein the seventh thread-like member is sewn to meander into a plane that intersects with the first surface and the second surface such that a plurality of first folded portions are formed at a side of the first surface and a plurality of second folded portions are formed inside the first substrate,
wherein the eighth thread-like member is sewn to meander into the plane that intersects with the first surface and the second surface such that a plurality of third folded portions are formed at a side of the second surface and a plurality of fourth folded portions are formed inside the first substrate, and
wherein the plurality of second folded portions are interlaced with the plurality of fourth folded portions, respectively.

10. The electric element according to claim 2,
wherein each of the first wire to fourth wire is configured to include:
a seven thread-like member having conductivity and provided into the first surface to meander on the first surface such that a plurality of first folded portions are formed at a first side of the first surface and a plurality of second folded portions are formed at second side of the first surface;
an eighth thread-like member having conductivity and provided into the second surface opposite to the first surface to meander on the second surface such that a plurality of third folded portions are formed at the first side of the second surface and a plurality of fourth folded portions are formed at the second side of the second surface;
a ninth thread-like member having conductivity and sewn to meander into a plane that intersects with the first surface and the second surface such that a plurality of fifth folded portions are formed at the first surface and a plurality of sixth folded portions are formed at the second surface, the plurality of fifth folded portions being interlaced with the plurality of first folded portions, respectively, and the plurality of sixth folded portions being interlaced with the plurality of third folded portions, respectively; and
a tenth thread-like member having conductivity and sewn to meander into the plane that intersects with the first surface and the second surface such that a plurality of seventh folded portions are formed at the first surface and a plurality of eighth folded portions are formed at the second surface, the plurality of seventh folded portions are interlaced with the plurality of second folded portions, respectively, and the plurality of eighth folded portions are interlaced with the plurality of fourth folded portions, respectively.

11. The electric element according to claim 1,
wherein the first conductive film is formed over a surface of the second substrate which is in contact with the first substrate, and
wherein the second conductive film is formed over a surface of the third substrate which is in contact with the first substrate.

12. An electronic device comprising:
an electric element configured to include:
a first substrate made of an insulator having bendability;
a second substrate provided over a first surface of the first substrate and having bendability and elasticity;
a first conductive film formed over the second substrate;
a third substrate having bendability and elasticity and provided over a position at which the third substrate overlaps the second substrate over a second surface of the first substrate opposite to the first surface;
a second conductive film formed at a position at which the second conductive film overlaps the first conductive film over the third substrate;
a first lead wire configured to include a first thread-like member having conductivity and sewn into the first substrate in a state having elasticity, the first thread-like member being extended from the first conductive film to the first substrate;
a second lead wire configured to include a second thread-like member having conductivity and sewn into the first substrate in a state having elasticity, the second thread-like member being extended from the second conductive film to the first substrate; and
a measurement circuit configured to measure electrical properties of the electric element through the first lead wire and the second lead wire, the measurement circuit being provided over the first substrate.

13. The electronic device according to claim 12,
wherein the first lead wire is configured to include:
a first wire configured to include a third thread-like member having conductivity and sewn into the first substrate in a state having elasticity, the third thread-like member being extended from a first end of the first conductive film to the first substrate; and
a second wire configured to include a fourth thread-like member having conductivity and sewn into the first substrate in a state having elasticity, the fourth thread-like member being extended from a second end of the first conductive film to the first substrate, and
wherein the second lead wire is configured to include:
a third wire configured to include a fifth thread-like member having conductivity and sewn into the first substrate in a state having elasticity, the fifth thread-like member being extended from a first end of the second conductive film to the first substrate; and
a fourth wire configured to include a sixth thread-like member having conductivity and sewn into the first substrate in a state having elasticity, the sixth thread-like member being extended from a second end of the second conductive film to the first substrate, and
wherein the measurement circuit is configured to measure a resistance value of the first conductive film through the first wire and the second wire, and measure a resistance value of a second conductive film through the third wire and the fourth wire.

14. The electronic device according to claim 13,
wherein the measurement circuit is configured to detect at least one of a bent state, a stretched state, and a contracted state of the first substrate at a position where the electric element is mounted, based on the measured resistance value of the first conductive film and the measured resistance value of the second conductive film.

15. The electronic device according to claim 13,
wherein the measurement circuit is configured to measure a capacitance value of a capacitor formed with the first substrate, the first conductive film, and the second conductive film, through one of the first wire and the second wire and one of the third wire and the fourth wire, and detect a state of pressing force applied to the electric element, based on the measured capacitance value.
